(19) United States
(12) Patent Application Publication
(10) Pub. No.: US 2005/0056312 A1
(43) Pub. Date: Mar. 17, 2005

(54) Bifacial structure for tandem solar cells

(76) Inventors: David L. Young, Golden, CO (US); Romel Noufi, Golden, CO (US)

Correspondence Address: PAUL J WHITE, SENIOR COUNSEL;NATIONAL RENEWABLE ENERGY LABORATORY (NREL), 1617 COLE BOULEVARD, GOLDEN, CO, 80401-3393, US

(21) Appl. No.: 10/895,474

(22) Filed: Nov. 22, 2004

(30) Foreign Application Priority Data
Mar. 14, 2003 (WO) PCT/US03/07815

(51) Int. Cl. H01L 31/00

(52) U.S. Cl. 136/258; 438/97

(57) ABSTRACT

The present invention provides a bifacial solar cell with two thin-film polycrystalline or amorphous cells formed on opposing sides of a transparent substrate so that high temperature deposition of all absorber layers can be completed before deposition of any window layers at lower temperatures, which would diffuse into the absorber layers at high temperatures, to avoid degradation or destruction of p/n junctions by such diffusion. The bifacial solar cell may be manufactured by either sequential or simultaneous deposition of absorber layers and by either sequential or simultaneous deposition of window layers of each cell.

### CONTRACTUAL ORIGIN OF INVENTION

The United States Government has rights in this invention under Contract No. DE-AC36-99G010337 between the United States Department of Energy and the National Renewable Energy Laboratory, a Division of the Midwest Research Institute.

### TECHNICAL FIELD

This invention relates to solar cells, and, more specifically, to multi-bandgap solar photovoltaic (SPV) cells for converting solar energy to electricity.

### BACKGROUND OF THE INVENTION

It is well known that the most efficient conversion of radiant energy to electrical energy with the least thermalization loss in semiconductor materials is accomplished by matching the photon energy of the incident radiation to the amount of energy needed to excite electrons in the semiconductor material to transcend the bandgap from the valence band to the conduction band. However, since solar radiation usually comprises a wide range of wavelengths, use of only one semiconductor material with one band gap to absorb such radiant energy and convert it to electrical energy results in large inefficiencies and energy losses to unwanted heat.

The benefits of using tandem solar cells incorporating both wide bandgap and narrow bandgap materials have been recognized. However, such tandem solar cells have been practically realized only in expensive, Group III-V crystalline materials and in less expensive, but low-efficiency, amorphous silicon (a-Si) thin films. Until this invention, tandem solar cells have not been available in less expensive, but high-efficiency, polycrystalline or amorphous thin film semiconductor materials. Modeling and other work has shown that high efficiency, tandem solar cells could, theoretically, result from certain combinations of polycrystalline thin films, but practical limitations in conventional fabrication techniques have heretofore prevented realization of practical tandem solar cell structures with such materials. For example, modeling work reported recently in Coutts et al., “Modeled performance of polycrystalline thin-film multijunction solar cells”, Progress in Photovoltaics and Applications 10, 2002, pp. 1-9, identified optimum bandgaps for two-junction, tandem thin-film solar cells and showed that a current-matched, 28% efficient tandem solar cell is theoretically possible with a top cell absorber of 1.7 eV and a bottom-cell absorber of 1.1 eV. Coincidentally, these 1.7 eV and 1.1 eV bandgaps for a theoretical 28% efficient tandem solar cell modeled by Coutts, et al., are an ideal match with the CuInSe₂ (0.95 eV)-CuGaSe₂ (1.7 eV) semiconductor material system. In other words, polycrystalline solar energy absorber materials can be made in this system that have either the desired higher bandgap of 1.7 eV or the desired lower bandgap of 1.1 eV, which the modeling predicts could achieve 28% efficiency, if they could be combined together in a tandem structure. It has also been shown that single-junction, polycrystalline CuInₓGa₁₋ₓSe₂/CdS cells have achieved absorption efficiencies greater than 18%, and that single-junction polycrystalline CuGaSe₂/CdS cells have reached efficiencies greater than 9%. See A. Contreras et al., “Progress toward 20% efficiency in Cu(In,Ga)Se₂ polycrystalline thin film solar cells”, Progress in Photovoltaics and Applications 7, 1999, pp. 311-316; V. Nadenau et al., Proceedings of the 14 European Photovoltaic Solar Energy Conference, Stephens & Associates, Bedford, U.K., 1997, p. 1250. Therefore, there is a lot of incentive to put these kinds of polycrystalline or even amorphous cells together in tandem solar cells to obtain the solar energy absorption efficiencies, cost effectiveness, and other benefits indicated by the modeling.

Unfortunately, the reality is that fabrication of these as well as many other polycrystalline or amorphous thin film tandem devices is fraught with problems. One of the most pervasive of these problems, which has been considered a “show-stopping” obstacle to further commercial development of such high-efficiency, tandem, polycrystalline or amorphous solar cell devices, is that the high deposition temperatures required to grow good quality polycrystalline, thin film solar energy absorber materials, such as the polycrystalline CuInₓGa₁₋ₓSe₂ and CuGaSe₂ materials mentioned above, cause severe degradation or destruction of previously deposited cells. Specifically, in conventional tandem solar cells, a first cell with a first bandgap is grown onto a substrate by depositing a first high temperature, polycrystalline solar energy absorber layer at temperatures above about 500° C. followed by a low-temperature window layer grown at temperatures below about 200° C. to create the p/n junction. In single junction polycrystalline or amorphous cells, such as the polycrystalline CuGaSe₂/CdS and Cu(In,Ga)Se₂/CdS heterojunction cells discussed above, the polycrystalline CuGaSe₂ and Cu(In,Ga)Se₂ absorber materials are preferably deposited at high temperatures, e.g., greater than 500° C., followed by a low temperature deposition of the CdS window layer on the CuGaSe₂ and Cu(In,Ga)Se₂ absorber materials to form the p/n heterojunction, preferably not more than about 200° C. The deposition of the CdS onto the polycrystalline CuGaSe₂ and Cu(In,Ga)Se₂ absorber materials at the lower temperature, instead of at a higher temperature, prevents the CdS from diffusing into the polycrystalline CuGaSe₂ and Cu(In,Ga)Se₂ materials, which would destroy the p/n heterojunction. The problem for use of these materials in a tandem cell structure arises in fabrication of the second cell over the first cell. The absorber material of the second cell, e.g., the CuGaSe₂ in the system being discussed, also has to be deposited at a high temperature, e.g., 350-700° C., preferably over 500° C., so the substrate and completed first cell have to be raised to that temperature. However, the completed first cell cannot survive in that temperature, because it will cause the CdS window layer of the completed first cell to diffuse into the CuGaSe₂ and Cu(In,Ga)Se₂ absorber layer of the first cell and destroy the p/n heterojunction. In other words, to avoid diffusion of the window layer into the absorber layer of the first cell and consequent degradation or destruction of the p/n junction of the first cell during deposition of the second cell in a conventional tandem cell construction with polycrystalline absorber materials, the shorting junction, which is usually used between the first and second cells in current matched tandem cells, and the second cell must be deposited at temperature below about 200° C. Thus, the second or top cell used in conventional tandem cells is practically limited to materials that may be deposited at temperatures below about 200° C. so as to not destroy the first cell. Because of this problem, most proposed polycrystalline tandem devices prior to this invention have been either coupled to single-crystal subcells or mechanically stacked to avoid the temperature limitations described above. Similar problems and limitations are encountered in amorphous tandem cells, for example, a-Si tandem cells in which the B-doped P-layers are temperature sensitive.

### SUMMARY OF THE INVENTION

Accordingly, a general object of this invention is to provide a method for forming a plurality of p/n junctions with polycrystalline or amorphous absorber materials for a multi-bandgap solar cell in which each of the absorber layers of the solar cell can be deposited under high temperature conditions without degrading or destroying previously deposited p/n junctions in the device. A more specific object of the present invention is to provide a method for forming a multi-bandgap tandem solar cell with polycrystalline or amorphous semiconductor absorbers having a top bandgap of about 1.7 eV and a bottom bandgap of about 1.1 eV.

An even more specific object of the present invention is to provide a method of forming a plurality of p/n junctions wherein one p/n junction is comprising polycrystalline or amorphous CuGaSe₂ and CdS and a second p/n junction comprising polycrystalline or amorphous Cu(In,Ga)Se₂ and CdS.

Another object of the present invention is to provide a multi-bandgap tandem solar cell having a wide bandgap polycrystalline or amorphous absorber and a narrow bandgap polycrystalline or amorphous absorber deposited at high temperatures, and corresponding window layers that are sensitive to the high temperature deposition of the absorber layer.

A more specific object of the present invention is to provide a solar cell with a first p/n junction composed of polycrystalline or amorphous CuGaSe₂ and CdS and a second p/n junction composed of polycrystalline or amorphous Cu(In,Ga)Se₂ and CdS.

To achieve the foregoing and other objects and in accordance with the purposes of the present invention, as embodied and broadly described herein, the present invention provides a method of forming a plurality of p/n junctions for a multi-bandgap solar cell with a polycrystalline or amorphous first absorber and a polycrystalline or amorphous second absorber deposited onto opposing sides of a transparent substrate at high temperatures followed by lower temperature deposition of first and second window layers onto the respective first and second absorbers to form first and second p/n junctions. Since the higher temperature depositions of the absorber layers for both cells are completed before either of the lower temperature window layers are deposited to complete the p/n junctions, neither of the p/n junctions need be exposed to high temperatures that would compromise its structural integrity by undesirable diffusion. The complementary absorber and window layers of each cell may be sequentially or simultaneously deposited to form the dual p/n junctions. The first and second p/n junctions may be heterojunctions, homojunctions, or combinations thereof. First and second layers of transparent conductors can be deposited onto the opposing sides or surfaces of a transparent substrate prior to deposition of the absorber layers to provide electric contacts or electrodes for the cells. Third and fourth conductors can be deposited onto the first and second windows, respectively, to form the complementary, opposite polarity contacts or electrodes for the cells. Either one or both of the latter electrodes can be transparent conductors, or, alternatively a metal grid may be the third transparent conductor, i.e., on the front cell, and a metal layer may be the fourth transparent conductor, i.e., on the back cell.

Further objects of the invention can be achieved according to this invention by a multi-bandgap solar cell comprising a transparent substrate having first and second surfaces, first and second transparent conductors deposited, respectively, onto the first and second surfaces. A wide bandgap absorber and a narrow bandgap absorber are deposited, respectively, at high temperature(s), onto the first and second transparent conductors, and first and second windows are deposited at lower temperature(s) onto the wide bandgap and narrow bandgap absorbers. The third and fourth transparent conductive media are respectively applied to the first and second windows to form first and second solar cells. A metal grid may be deposited onto the second transparent conductive medium, and a metal layer may be deposited onto the fourth transparent conductive medium.

### BRIEF DESCRIPTION OF THE DRAWINGS

The accompanying drawings, which are incorporated in and form a part of the specification, illustrate the preferred embodiments of the present invention, and together with the descriptions serve to explain the principles of the invention.

In the Drawings:

FIG. 1 is a cross-section illustration of a bifacial tandem solar cell device with polycrystalline or amorphous semiconductor heterojunctions fabricated and structured according to the present invention; and

FIG. 2 is a cross-section illustration of a bifacial tandem solar cell device with a polycrystalline or amorphous semiconductor heterojunction and a polycrystalline or amorphous semiconductor homojunction.

### DETAILED DESCRIPTION OF THE PREFERRED EMBODIMENTS

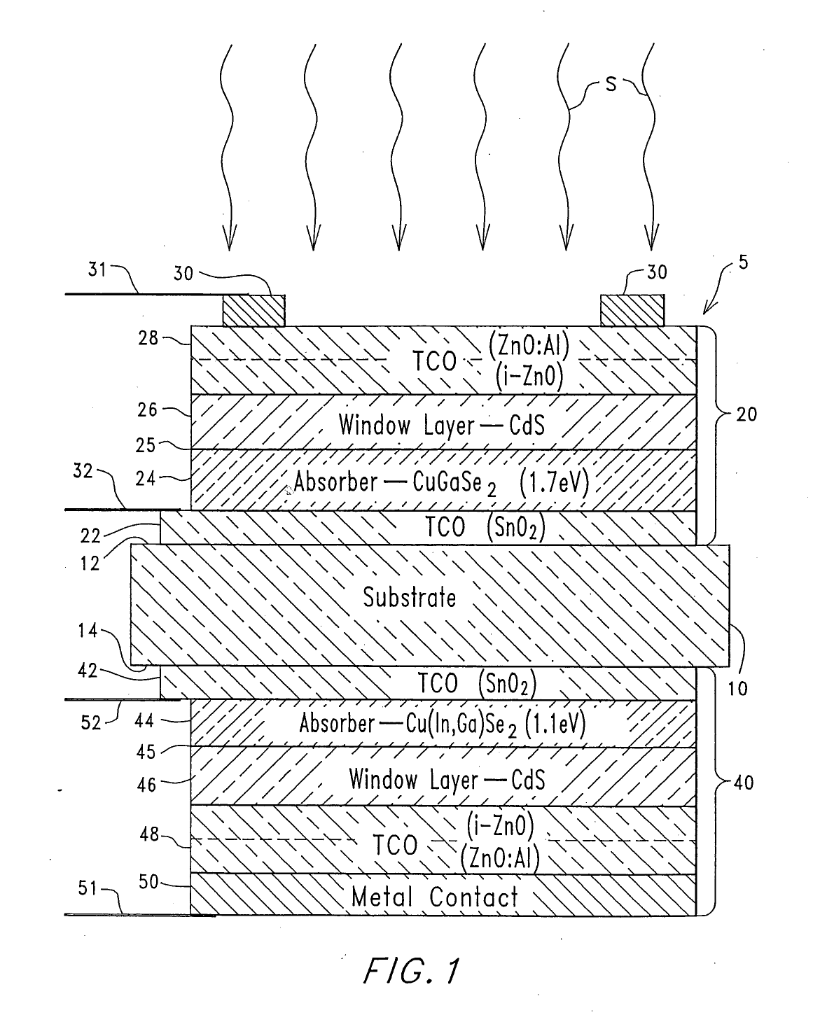

A solar cell 5 fabricated and structured in accordance with the present invention is illustrated diagrammatically in FIG. 1, including a transparent substrate 10 having a first surface 12 and a second surface 14 with first solar cell 20 grown onto the first surface 12 and second solar cell 40 is grown onto the second surface 14. The transparent substrate 10 may be any transparent substrate capable of supporting a solar cell 20, 40 on each side. Examples of suitable substrates include glass substrates and quartz substrates of any suitable thickness, but preferably in a range between about 1 and 5 mm, or the transparent substrate 10 can be a thin transparent metal or polymer.

As illustrated in FIG. 1, first solar cell 20, also called the front cell, includes a first absorber layer 24 with a larger bandgap, for example 1.7 eV, a first window layer 26 interfacing the first absorber layer 24 to form a p/n junction 25, and first front and back transparent conductor (“TC”) layers 22, 28, respectively. Second solar cell 40, also called the back cell, includes a second absorber layer 44 with a smaller bandgap, for example, 1.1 eV, a second window layer 46 interfacing the second absorber layer 44 to form a p/n junction 45, and a second front and back transparent conductor layers 42, 48, respectively.

A significant feature of this invention is the ability to deposit both of the absorber layers 24, 26 of the first and second cells 20, 40, respectively, at high temperatures, e.g., greater than 500° C., prior to depositing either of the window layers 26, 46. Then, after both of the absorber layers 24, 44 are deposited at higher temperature(s), both of the window layers 26, 46, such as CdS, can be deposited on the absorber layers 24, 44, respectively, to form the p/n junctions 25, 45 at low enough temperature(s) to substantially prevent degradation of the p/n junctions from diffusion. Consequently, either one or both of the window layers 26, 46 can be deposited at low temperature(s), such as 200° C. or less. Therefore, this invention provides the advantages of two cells 20, 40, both with absorber layers 24, 44, such as polycrystalline or amorphous CuGaSe₂ and Cu(In,Ga)Se₂, of the high quality obtainable at high deposition temperatures, but without the p/n junction degradation or destruction that otherwise would accompany raising temperature sensitive p/n junctions to high temperatures. For the particular example multi-junction solar cell 5 shown in FIG. 1, the solar radiation S is incident on the first cell 20. Then, whatever solar radiation that is not absorbed in the first cell 20 propagates through the transparent substrate to the second cell 40. Therefore, in conventional terminology, the first cell 20 can also be called the front cell, and the second cell 40 can also be called the back cell. Likewise, first cell 20 has a front conducting layer 28 and a back conducting layer 24, and the second cell 40 also has a front conducting layer 42 and a back conducting layer 48. Since incident radiation S has to reach the absorbers 24, 44 of the respective cells 20, 40, to be converted to electricity, the front conducting layer 28, the window layer 26, and the back conducting layer 22 of the front cell 20 have to be adequately transparent to the incident radiation to avoid any significant absorption of light energy that would decrease efficiency of the cells 20, 40, as do the substrate 10 and the front conducting layer 42 of the back cell 40. The back conducting layer 48 of the back cell 40 can also be transparent, so that any unabsorbed radiation emerging from the second absorber layer 46 can be reflected by the metal contact 50 back into the second absorber layer 44, if desired. The metal grid 30 on the front of the device 5 and the metal contact 50 on the back of the device 5 can accommodate electrical connections to the device via respective leads 31, 51, as is well-known to persons skilled in the art. The other leads 32, 52 of the respective cells 20, 40 can be connected to the respective transparent conducting layers 22, 42, as is also well-known to persons skilled in the art. If it is desired to operate the front and back cells 20, 40 in series, the leads 32, 51 can be connected together with leads 31, 52 connected to opposite poles of a load. On the other hand, if it is desired to operate the cells 20, 40 in parallel, leads 31, 51 can be connected together to one side of a load with leads 32, 52 connected together to the opposite side of the load, as is also well-known in the art. Since the solar radiation S reaches the front cell 20 before the back cell 40, the first absorber 24 would normally have a higher bandgap than the second absorber 44 so that it absorbs higher energy portions of the solar radiation S and allows lower energy portions of the solar radiation S to propagate through the first cell 20 to the back cell 40. The absorber layer 44 of the back cell 40 then absorbs lower energy portions of the solar radiation S that propagated through the front cell 20.

According to this invention, the various layers of the device 5 are deposited and grown outwardly in opposite directions from the substrate 10 in a sequence, so that the high temperature depositions on both sides of the substrate 10 are completed before temperature sensitive layers and materials are deposited on either side of the substrate 10. Therefore, transparent conducting layers 22 and 42 are deposited first onto the respective first and second surfaces 12, 14 of substrate 10. First and second transparent conducting layers 22, 42 may be comprised of a transparent conductive oxide, such as tin oxide or zinc oxide, which can withstand the deposition temperatures required for the absorber and other layers to follow, and preferably with a thickness between 0.5 and 1 microns.

In the example embodiment illustrated in FIG. 1, the first and second absorber layers 24, 44 are deposited onto the first and second transparent conducting layers 22, 42. The absorber layers 24, 44 are typically thin-film, p-type semiconductors having a thickness between about 2-4 microns. First absorber layer 24 is a wider bandgap semiconductor for the reasons explained above. An example of a suitable wide bandgap semiconductor for first absorber 24, is a polycrystalline or amorphous CuGaSe₂ semiconductor. Generally, the bandgap may be adjusted by varying the amount of gallium added to the semiconductor. Second absorber layer 44 is a narrow bandgap semiconductor, such as a polycrystalline or amorphous Cu(In,Ga)Se₂ (also sometimes written as CuInₓGa₁₋ₓSe₂) While not essential to this invention, it is particularly beneficial to provide the first absorber 24 with polycrystalline or amorphous CuGaSe₂ having a bandgap of about 1.7 eV and the second absorber 44 with polycrystalline or amorphous Cu(In,Ga)Se₂ having a bandgap of about 1.1 eV for optimum conversion efficiency according to the Coutts et al. model discussed above. These and other typical absorber materials are usually deposited at higher temperatures, e.g., greater than 500° C., as will be discussed in more detail below. Therefore, they are both deposited before depositing the window layers 26, 46 to form the junctions 25, 45 of the respective first and second cells 20, 40, as will also be discussed in more detail below.

The first and second window layers 26, 46 for the respective first and second cells 20, 40 are typically thin-film, n-type semiconductors that are deposited onto first and second absorber layers 24 and 44 to form first and second p/n junctions 25 and 45. The resulting p/n junctions may be homojunctions or heterojunctions as desired. An example of a suitable semiconductor materials for first and second window layers 26, 46 include cadmium sulfide, especially when used in combination with the polycrystalline or amorphous CuGaSe₂ and polycrystalline or amorphous Cu(In,Ga)Se₂ first and second absorber layers 24, 44, discussed above, to form heterojunctions 25, 45. To avoid any confusion, it is probably worth noting that persons skilled in the art understand that p/n junction is a generic term that applies to any junction formed by p-type and n-type semi-conductor materials, regardless of whether they are arranged so that the light is incident first on the p-type material or so that the light is incident first on the n-type material and regardless of whether there is or is not an intrinsic layer between them. The first and second window layers 26, 46 can have any appropriate thickness, for example, between about 0.05 and 3 microns and are usually deposited at lower temperatures, for example, 200° C. or less, to avoid deleterious diffusion into the absorber layers 24, 44.

The third and fourth transparent conducting layers 28, 48 are deposited onto exposed surfaces of the first and second window layers 26, 46, and may also be comprised of a transparent conductive oxide, such as tin oxide or zinc oxide. In one embodiment, first and second transparent conducting layers 22, 42 are tin oxide and third and fourth transparent conductive layers 28, 48 are zinc oxide layers, as shown in FIG. 1. The ZnO can be deposited in two sublayers—one comprising intrinsic ZnO to complete the junction structure and the other Al-doped ZnO:Al for extra conductor electrons. The third and fourth transparent conductive layers 28, 48 may have any appropriate thickness, for example, between about 0.5 and 1 micron.

Optionally, a metal current collection grid 30 may be deposited onto third transparent conducting layer 28 to provide one or more terminal electrical connections. A metal layer 50 may be deposited onto fourth transparent conducting layer 48 and may possess reflective properties for reflecting light back into the back and front cells 40, 20, as explained above. Suitable types of metals for the grid 30 and the layer 50 include molybdenum, aluminum, silver, and others.

In operation, incident light passes through metal current collection grid 30 (if present) and into first cell 20. Light having shorter wavelengths (i.e., higher energy) is absorbed by first cell 20 to provide a photovoltage potential across first p/n junction 25. Light having longer wavelengths (i.e., lower energy) passes through first cell 20, through transparent substrate 1 and is absorbed by second cell 40 to provide a photovoltage potential across second p/n junction 45. Light that passes through first and second cells 20, 40 may reflect off metal layer 50 and travel back into the cells 20, 40 for additional absorption.

The solar cell 5 illustrated in FIG. 1 may be manufactured by sequentially or simultaneously depositing absorber layers 24, 44 of first and second cells 20, 40 onto the first and second surfaces 12, 14 of transparent substrate 10 so that the temperature sensitive window layers 26, 46 in each cell are deposited at lower temperature conditions after both the first and second absorber layers 24, 44 are deposited under high temperature conditions.

Referring to the tandem solar cell 5 illustrated in FIG. 1, first and second transparent conducting layers 22, 42 may be deposited onto transparent substrate 10 by conventional deposition methods, such as by low pressure chemical vapor deposition. The resulting composite structure may then be placed in a vacuum deposition chamber and heated to a higher temperature range, such as between about 350 to 700° C., to provide deposition (e.g., co-evaporation) of the first and second absorber layers 24, 44 onto first and second transparent conducting layers 22 and 42, respectively. For example, in embodiments incorporating a glass substrate 10, the composite structure may be heated to about/500° C. to deposit the absorber layers. In embodiments incorporating a quartz substrate, the deposition temperature may be about 650° C. or higher.

The first and second absorber layers 24, 44 may be sequentially deposited by performing vacuum deposition on one side 12 or 14 of the substrate 10 to deposit one absorber 24 or 44, flipping or rotating the substrate 10, and performing vacuum deposition on the other side 12 or 14 of the substrate 10 to deposit the other absorber 24 or 44. The choice of which absorber layer 24 or 44 to deposit first depends on which absorber 24 or 44 is more tolerant to the deposition conditions of the second-deposited absorber 24 or 44. If both of the first and second absorber layers 24, 44 can be deposited at the same temperature, it is also possible to simultaneously deposit both absorber layers 24, 44.

The resulting composite, including transparent substrate 10, first and second transparent conducting layers 22, 42 and first and second absorber layers 24, 44 may then be removed from the vacuum and placed in a chemical bath at between about 50 and 100° C. to deposit the first and second window layers 26, 46 onto the respective first and second absorber layers 24, 44. Alternatively, first and second window layers 26, 46 may be sequentially or simultaneously deposited by sputtering or evaporation methods. Third and fourth transparent conducting layers 28, 48 are then deposited onto first and second windows 26, 46 by conventional deposition methods such as RF magnetron sputtering at room temperature. Metal grid 30 and metal plate 50 may be deposited onto opposing ends of solar cell 5, if desired.

One characteristic of the present method of manufacturing a tandem solar cell is that the high temperature deposition of both the first and second absorber layers 24, 44 is performed before either of the temperature-sensitive first and second window layers 26, 46 are deposited. If each of the first and second cells 20, 40 are grown sequentially as in conventional methods of manufacturing tandem solar cells, the temperature sensitive window layer and the junction formed during deposition of the first cell 20 may be destroyed by the high-temperature deposition of the absorber layer of the second cell 40 (or vice-versa). Thus, the present method overcomes this problem by either sequentially or simultaneously depositing both absorber layers 24, 44 prior to depositing either one of the window layers 26, 46. Furthermore, this method also reduces product throughput time and energy consumption, resulting in significant cost-savings.

In the multi-junction solar cell device 5 illustrated in FIG. 1 with heterojunctions 25, 45, persons skilled in the art may recognize that the second or back cell 40 is inverted from normal cells in relation to the incident sun light S, i.e., the light S reaches the second absorber 44 without passing through the window layer 46. Thus, it may be important to keep the second absorber layer 44 thin enough so that most absorption of light energy still occurs near the heterojunction 45 to optimize conversion efficiencies. While a thinner absorption layer 44 may tend to transmit more light than a thicker absorption layer would, this problem is mitigated by the reflective metal contact layer 50, which reflects such unabsorbed light back into the back cell 40, i.e., in the usual, non-inverted manner, for additional absorption.

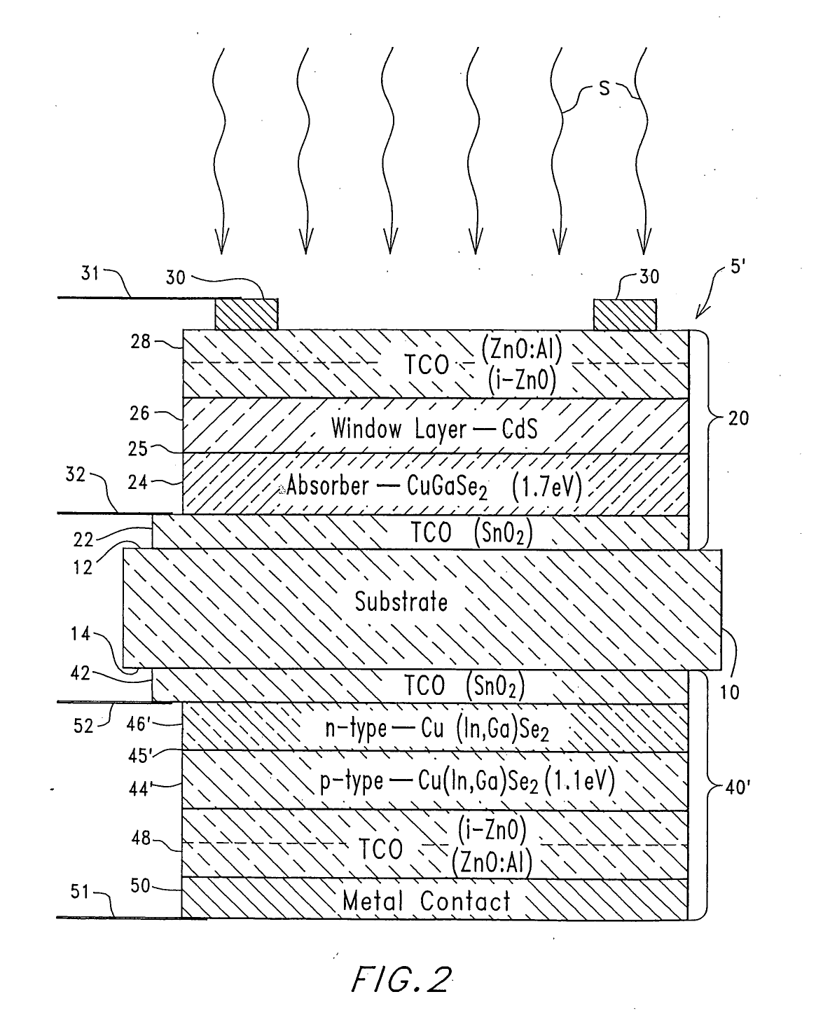

This issue can also be addressed in another manner, as illustrated by the multi-junction solar cell device 5′ in FIG. 2, by making the second or back cell 40′ with a homojunction 45′. For example, the second cell 40′ can be structured with a n-type polycrystalline or amorphous Cu(In,Ga)Se₂ window layer 46′ and a p-type polycrystalline or amorphous Cu(In,Ga)Se₂ absorber layer 44′, both of which can be deposited at a high temperature to form the p/n homojunction 45′. Therefore, by using the bifacial technique of this invention for fabricating this kind of solar cell structure 5′, the window layer 46′ and absorber layer 44′ of the second cell 40′ as well as the absorber layer 24 of the first cell 20 can be deposited at higher temperature(s) before the lower temperature deposition of the window layer 26 of the first cell 20. Therefore, as explained above for the solar cell device 5 of FIG. 1, the bifacial fabrication technique of this invention also enables fabrication of the multi-junction solar cell device 5′ of FIG. 2 without destroying the heterojunction 25 with high temperatures from deposition of subsequent layers. Examples of suitable materials for forming homojunctions include Cu(In,Ga)Se₂, CuGaSe₂, CuGaS₂, CdZnTe, CdMnTe, CdMgTe, CdTe, and CuInSe₂.

Solar cells manufactured according to the present method possess several beneficial characteristics. As illustrated in FIG. 1, the first and second cells 20 and 40 are optically connected, but do not have to be electrically connected unless desired. For example, the cells may be connected in series to an external load (not shown) to provide a flow of electrons through the solar cell 5 and the external load to produce a photocurrent that performs work on the external load.

Furthermore, first and second solar cells 20, 40 produced according to the present method may be easily laser scribed to form a plurality of scribed cells (not shown) in each of cells 20 and 40. The scribed cells within the first and second cells 20, 40 may be electrically connected in series to add voltage between the scribed cells. By depositing complementary layers of each cell as described above, each deposited layer may be scribed prior to deposition of the subsequent layer. This allows for efficient scribing characteristics not necessarily realized by conventional tandem cells.

By laser scribing first and second cells 20 and 40, multiple electrical configurations may also be accomplished. In one embodiment, both cells are optically aligned and share the same area. A four terminal connection to the cells is then current matched. In another embodiment, the first and second cells 20, 40 have different areas which allows almost any voltage output possible in the first and second cells 20, 40. A four terminal connection could draw off of the voltage from the first and second cells, or add the voltages of both cells. These terminal connections may be accomplished without the use of a metal grid.

### EXAMPLE

An embodiment of the tandem solar cell illustrated in FIG. 1 was grown according to the method described herein. SnO₂:F thin films were grown on each side of soda-lime glass by chemical vapor deposition. Next, the coated substrate was placed in a holding bracket, which was then placed into a deposition chamber. A 2 micron-thick layer of Cu(In,Ga)Se₂ was then grown by co-evaporation using a 3-stage deposition with a maximum temperature of 605° C. for about 15 minutes. The substrate was then flipped in the holding bracket, and a 2 micron-thick layer of CuGaSe₂ was grown by similar 3-stage process. The maximum temperature during the CuGaSe₂ growth was 61° C. for 10 minutes. The p/n junctions were then formed simultaneously for both cells in a n-CdS chemical-bath deposition at about 60° C. Two ZnO layers, one intrinsic and the other conductive (ZnO:Al, were grown by RF magnetron sputtering at room temperature onto the CdS layers of each cell. The cells were then completed by depositing Al grid contacts onto the ZnO layers.

The resulting cell was subjected to several solar cell efficacy tests. X-ray diffraction scans showed the films to be phase pure. Scanning electron microscopy images of CuGaSe₂, and Cu(In,Ga)Se₂ revealed large-grain dense films with good nucleation to the SnO₂ back contacts. Electron probe microanalysis demonstrated suitable film composition given the deposition rates.

The foregoing description and the illustrative embodiments of the present invention have been presented in detail in varying modes, modifications, and alternate embodiments. It should be understood, however, that the foregoing description of the best modes of the present invention is exemplary only, and that numerous other modifications and alternative embodiments and modes of the invention will readily occur to persons skilled in the art. Therefore, the scope of the present invention is to be limited only by the claims below, as properly interpreted by applicable law, and not by the exact constructions, process steps, or parameters shown or described above.

The words “comprise,” “comprises,”, “comprising,”, “include”, “including”, and “includes” when used in this specification or in the following claims are intended to be open-ended, i.e., to specify the presence of stated features or steps, but they do not preclude or exclude the presence or addition of one or more features, steps, or groups thereof, which are not stated or recited. The word “about” when used in relation to bandgap in this specification or in the following means within 0.1 eV. The term “high temperature” when used in this specification or in the following claims means a temperature high enough to cause sufficient diffusion of window layer material into absorber layer material to degrade the performance of the p/n junction in a significant manner, i.e., enough degradation to cause persons skilled in the art to believe it should be avoided or mitigated. The term “low temperature” when used in this specification means less than “high temperature” as defined above. Specific examples of such high temperatures and low temperatures depend on particular materials used, time of exposure, and other factors.

1. A method of fabricating a multi-bandgap solar cell device with polycrystalline or amorphous semiconductor absorber material that requires high temperature deposition for at least two cells and at least two polycrystalline or amorphous semiconductor window layer materials that require low temperature deposition to form p/n junctions in combination with the absorber materials, comprising:
depositing a first layer of polycrystalline or amorphous semiconductor absorber material with a first bandgap over one of two opposing sides of a transparent substrate in high temperature conditions and depositing a second layer of polycrystalline or amorphous semiconductor absorber material with a second bandgap over another of the two opposing sides of the transparent substrate in high temperature conditions; and
depositing a first window layer of polycrystalline or amorphous semiconductor material in low temperature conditions on the first layer of absorber material to form a first p/n junction and depositing a second window layer of polycrystalline or amorphous semiconductor material in low temperature conditions on the second layer of absorber material to form a second p/n junction.

2. The method of claim 1, wherein the high temperature is in a range between about 350 and 700° C.

3. The method of claim 1, wherein the high temperature is in a range between 500 and 700° C.

4. The method of claim 1, wherein the low temperature is at or below about 200° C.

5. The method of claim 1, wherein the first and second absorber layers are deposited sequentially.

6. The method of claim 1, wherein the first and second absorber layers are deposited simultaneously.

7. The method of claim 1, wherein deposition of the first and second absorber layers is by high-temperature vacuum deposition.

8. The method of claim 1, wherein deposition of the first and second absorber layers comprises heating the substrate to a first high temperature to deposit the first absorber layer and heating the substrate to a second high temperature that is higher than the first high temperature to deposit the second absorber layer.

9. The method of claim 1, wherein the first absorber layer comprises CuGaSe₂.

10. The method of claim 9, wherein the first absorber layer has a bandgap of 1.7 eV.

11. The method of claim 10, wherein the second absorber layer comprises Cu(In,Ga)Se₂ with a bandgap less than 1.7 eV.

12. The method of claim 11, wherein the second absorber layer has a bandgap of 1.1 eV.

13. The method of claim 1, wherein the first and second windows are deposited simultaneously.

14. The method of claim 1, wherein the first and second windows are deposited sequentially.

15. The method of claim 1, wherein the first and second windows are deposited in a chemical bath.

16. The method of claim 11, wherein the first and second window layers comprise CdS.

17. The method of claim 1, wherein at least one of the first and second p/n junctions is a heterojunction.

18. The method of claim 1, wherein at least one of the first and second p/n junctions is a homojunction.

19. The method of claim 18, wherein the first absorber is deposited at a first temperature, the second absorber is deposited at a second temperature, the first window is deposited at a third temperature and the second window is deposited at a fourth temperature wherein the fourth temperature is lower than or equal to the third temperature, which is lower than or equal to the second temperature, which is lower than or equal to the first temperature.

20. The method of claim 1, comprising depositing first and second transparent conductor layers onto the opposing sides of the substrate prior to depositing the first and second absorber layers, and then depositing the first absorber layer onto the first transparent conductor layer and the second absorber onto the second transparent conductor layer.

21. The method of claim 20, wherein the first and second transparent conductor layers are deposited by chemical vapor deposition.

22. The method of claim 20, wherein the first and second transparent conductor layers are deposited sequentially or simultaneously.

23. The method of claim 20, wherein the first and second transparent conductor layers are deposited simultaneously.

24. The method of claim 20, including depositing a third transparent conductor layer onto the first window layer and a fourth transparent conductor layer onto the second window layer.

25. The method of claim 24, wherein the third and fourth transparent conductors are deposited sequentially or simultaneously.

26. The method of claim 24, wherein the third and fourth transparent conductors are deposited by RF magnetron sputtering.

27. The method of claim 24, further comprising depositing a metal grate onto the third transparent conductor and a metal layer onto the fourth transparent conductor.

28. The method of claim 27, wherein the metal grid and the metal layer are deposited sequentially or simultaneously.

29. The method of claim 27, wherein the step of depositing the metal grid and the metal layer occurs at room temperature.

30. A method of fabricating a multi-bandgap solar cell device with polycrystalline or amorphous semiconductor absorber materials with different bandgaps for at least two cells of the device, comprising:
depositing a first layer of polycrystalline or amorphous semiconductor absorber material with a first bandgap over one of two opposing sides of a transparent substrate in high temperature conditions and depositing a second layer of polycrystalline or amorphous semiconductor material with a second bandgap over another of the two opposing sides of the transparent substrate in high temperature conditions.
depositing a second window layer on the second absorber layer in high temperature conditions to form a second p/n junction for a second cell on said one of the two opposing sides of the transparent substrate; and
depositing a first window layer on the first absorber layer in low temperature conditions to form a first p/n junction for a first cell on said another of the two opposing sides of the transparent substrate.

31. The method of claim 30, wherein the second p/n junction is a homojunction.

32. The method of claim 31, wherein the first p/n junction is a heterojunction.

33. A method of fabricating a multi-bandgap solar cell device with polycrystalline or amorphous semiconductor absorber materials with different bandgaps for at least two cells of the device, comprising:
depositing a first layer of polycrystalline or amorphous semiconductor absorber material with a first bandgap over one of two opposing sides of a transparent substrate in high temperature conditions to form an absorber layer of a first cell on said one of the two opposing sides of the transparent substrate;
depositing polycrystalline or amorphous semiconductor material with a second bandgap and doped to be either n-type or p-type over another of the two opposing sides of the transparent substrate in high temperature conditions followed by depositing more of the polycrystalline or amorphous material with the second bandgap, but oppositely doped to be either p-type or n-type, in high temperature conditions to form a homojunction with a second window layer and a second absorber layer for a second cell on said another of the two opposing sides of the transparent substrate; and then
depositing a first window layer on the first absorber layer in low temperature conditions, which do not result in diffusion of the first window layer into the first absorber layer, to form a heterojunction of said first cell.

34. The method of claim 33, including depositing transparent conducting layers on the two opposing sides of the transparent substrate prior to deposition of the absorber layers and window layers, and depositing additional transparent conducting layers on the cells after deposition of the absorber and window layers.

35. A multi-bandgap solar cell comprising:
a transparent substrate having first and second opposing surfaces;
a first transparent conductor formed onto the first surface of the substrate and a second transparent conductor formed onto the second surface of the substrate;
a first absorber layer of polycrystalline or amorphous semiconductor material with a first bandgap formed onto the first transparent conductor and a second absorber layer of polycrystalline or amorphous semiconductor material with a second bandgap formed onto the second transparent conductor;
a first window layer formed onto the wide bandgap absorber to form a first p/n junction, and a second window layer formed onto the narrow bandgap absorber to form a second p/n junction; and
a third transparent conductor layer applied to the first window to form a first solar cell, and a fourth transparent conductor layer applied to the second window to form a second solar cell.

36. The solar cell of claim 35, wherein the transparent substrate comprises glass.

37. The solar cell of claim 35, wherein the transparent substrate comprises quartz.

38. The solar cell of claim 35, wherein each of the transparent conductors comprises a transparent conductive oxide.

39. The solar cell of claim 38, wherein the transparent conductive oxide comprises tin oxide or zinc oxide.

40. The solar cell of claim 38, wherein the first and second transparent conductors comprise tin oxide and the third and fourth transparent conductors comprise zinc oxide.

41. The solar cell of claim 35, wherein the first bandgap and second bandgap absorber layers are p-type semiconductor materials.

42. The solar cell of claim 35, wherein the first bandgap and second bandgap absorber layers comprise CuGaSe₂.

43. The solar cell of claim 35, wherein the second bandgap absorber layer comprises Cu(In,Ga) Se₂.

44. The solar cell of claim 35, wherein the first and second window layers are n-type semiconductor material.

45. The solar cell of claim 35, wherein the first and second window layers comprise cadmium sulfide.

46. The solar cell of claim 35, wherein at least one of the first and second p/n junctions is a homojunction.

47. The solar cell of claim 35, wherein the homojunction is formed from materials selected from the group consisting of Cu(In,Ga)Se₂, CuGaSe₂, CuGaS₂, CdZnTe, CdMnTe, CdMgTe, CdTe, and CuInSe₂.

48. The solar cell of claim 35, further comprising a metal grid applied onto the third transparent conductor layer and a metal layer applied onto the fourth transparent conductor layer.

49. The solar cell of claim 35, wherein the metal layer and metal grid comprise molybdenum, aluminum, or silver.

50. The solar cell of claim 35, wherein the first bandgap is about 1.7 eV.

51. The solar cell of claim 35, wherein the second bandgap is about 1.1 eV.
